(19) United States
(12) Patent Application Publication
(10) Pub. No.: US 2009/0274353 A1
(43) Pub. Date: Nov. 5, 2009

(54) BACKGROUND MAGNETIC RESONANCE IMAGING

(75) Inventors: Alastair J. Martin, Novato, CA (US); Oliver M. Weber, Bern (CH)

Correspondence Address: PHILIPS INTELLECTUAL PROPERTY & STANDARDS, P. O. Box 3001, BRIARCLIFF MANOR, NY, 10510, US

(73) Assignee: Koninklijke Philips Electronics N. V., Eindhoven (NL)

(21) Appl. No.: 12/296,938

(22) PCT Filed: Mar. 16, 2007
(86) PCT No.: PCT/US07/64180

§ 371 Date: Oct. 13, 2008

Related U.S. Application Data
(60) Provisional application No. 60/744,754, filed on Apr. 13, 2006.

(51) Int. Cl. G01R 33/48; G06K 9/00

(52) U.S. Cl. 382/131; 324/309

(57) ABSTRACT

An imaging controller (46) performs data acquisition in first and second scanning processes (48, 50), the first scanning process (48) including a set of data acquisitions (92, 96, 106, 122, 124, 126, 128, 130) and periods of inactivity (90, 94, 102, 110, 142, 152). A workflow manager (58) monitors the first scanning process (48), detects the periods of inactivity (90, 94, 102, 110, 142, 152) and enables data acquisition of the second scanning process (50) when the first scanning process (48) is inactive.

The present application relates to diagnostic imaging systems and methods. It finds particular application in conjunction with improving the throughput of the magnetic resonance imaging (MRI) systems and will be described with particular reference thereto. However, it also finds application in Positron Emission Tomography (PET), Single Photon Emission Tomography (SPECT) systems, Computed Tomography systems (CT), and the like.

Magnetic resonance imaging scanners typically include a main magnet, typically superconducting, which generates a spatially and temporally constant magnetic field B₀ through an examination region. A radio frequency (RF) coil, such as a whole-body coil, a local coil, and the like, and a transmitter are typically tuned to the resonance frequency of the dipoles to be imaged in the magnetic B₀ field. The coil and transmitter are used to excite and manipulate the dipoles. Spatial information is encoded by driving the gradient coils with currents to create magnetic field gradients in addition to the magnetic B₀ field across the examination region in various directions. Magnetic resonance signals can be acquired by the same or separate receive-only RF coil, demodulated, filtered and sampled by an RF receiver and finally reconstructed into an image on dedicated or general-purpose hardware.

Although the magnetic resonance imaging is now a routinely performed diagnostic examination, the MR exams, however, tend to be relatively slow. Typically, a patient examination takes from 30 to 90 minutes depending on the number and type of magnetic resonance scan sequences to be performed. Typically, after the patient arrives for the exam, a pilot scan is performed. After the pilot scan is conducted, the scanner is inactive as the technologist awaits the data to be reconstructed, review the reconstructed image, and make adjustments. After that, a set of scans is scheduled and executed, each of which requires reconstruction and, possibly, further adjustments. Again, the scanner is inactive. Frequently, one of the sequences requires breath-hold periods. In such sequence, the scanner is active only during breath-holds, typically less than 50% of the time, with inactive rest periods allowed for the patient to recover between the breath-hold periods.

Several solutions have been suggested to improve the magnetic resonance scan sequences design and techniques that reduce the duration of specific MR exams. These solutions include turbo (or fast) spin echo techniques, echo planar imaging, steady state techniques and sensitivity encoding for fast MRI (SENSE) by a use of several receivers in parallel. These solutions mainly serve to shorten scan time but do not shorten the periods of scanner inactivity between segments of the imaging procedure. Moreover, such solutions are not applicable for all image acquisitions and on others may adversely affect image quality, e.g. contrast.

Mechanisms that can increase the efficiency of an MR examination without compromising contrast can have a substantial benefit on the number of patients that can be scanned per day and therefore on the cost effectiveness of the MRI examination.

The present application provides new and improved apparatuses and methods which overcome the above-referenced problems and others.

In accordance with one aspect, an imaging system is disclosed. An imaging controller performs data acquisition in first and second scanning processes, the first scanning process including a set of data acquisitions and periods of inactivity. A workflow manager monitors the first scanning process, detects the periods of inactivity and enables data acquisition of the second scanning process when the first scanning process is inactive.

In accordance with another aspect, an imaging method is disclosed. Data for a first scanning process is intermittently acquired. The first scanning process is monitored. Periods of inactivity in the first scanning process, which occur when the data in the first scanning process is not being acquired, are detected. The data for a second scanning process is acquired when the first scanning process is inactive.

In accordance with another aspect, an imaging apparatus is disclosed. An imaging controller executes data acquisition in first and second scanning processes, the first scanning process including a set of data acquisitions and periods of inactivity. A workflow manager performs the steps of: continually monitoring the first scanning process; detecting a start of each period of inactivity in the first scanning process which period of inactivity occurs when the data in the first scanning process is not being acquired; automatically one of starting and resuming the data acquisition in the second scanning process when the start of each period of inactivity is detected, and automatically suspending the data acquisition in the second scanning process when a new data acquisition request is submitted in the first scanning process. A reconstruction processor, reconstructs (a) the data acquired in the first scanning process after each data acquisition request is completed and (b) the data acquired in the second scanning process.

One advantage is that an overall MR examination time is reduced by running a time consuming slow scan sequence in parallel to the primary scan sequence.

Still further advantages of the present invention will be appreciated to those of ordinary skill in the art upon reading and understand the following detailed description.

The invention may take form in various components and arrangements of components, and in various steps and arrangements of steps. The drawings are only for purposes of illustrating the preferred embodiments and are not to be construed as limiting the invention.

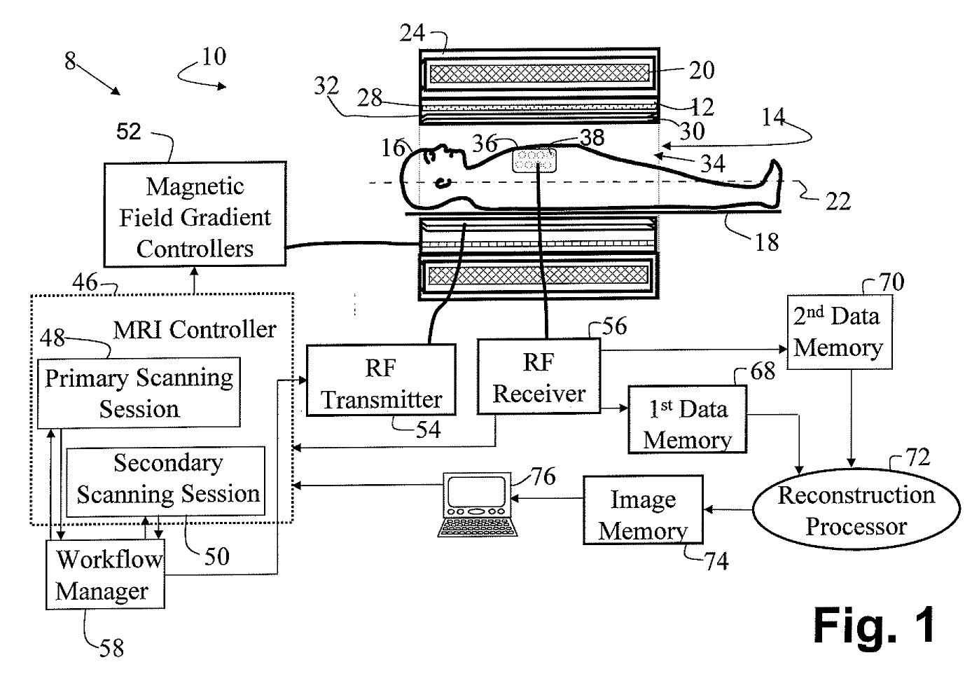

FIG. 1 is a diagrammatic illustration of a magnetic resonance imaging system; and

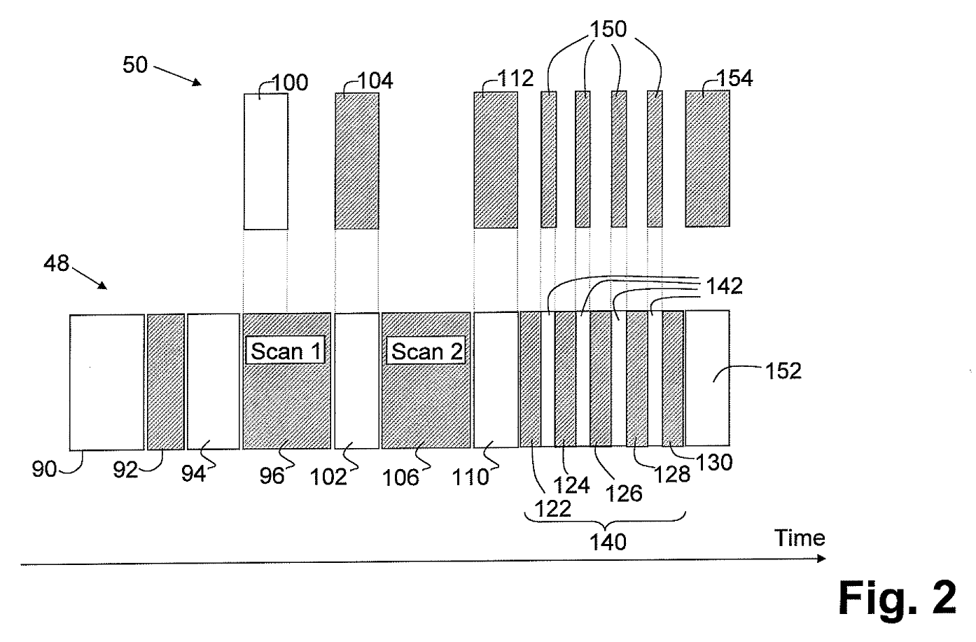

FIG. 2 is a block diagram of two parallel scanning processes.

With reference to FIG. 1, a magnetic resonance imaging system 8 includes a scanner 10 including a housing 12 defining an examination region 14, in which a patient or other imaging subject 16 is disposed on a patient or subject support or bed 18. A main magnet 20 disposed in the housing 12 generates a main magnetic field Bo in the examination region 14. Typically, the main magnet 20 is a superconducting magnet surrounded by cryo shrouding 24; however, a resistive or permanent main magnet can also be used. Magnetic field gradient coils 28 are arranged in or on the housing 12 to superimpose selected magnetic field gradients on the main magnetic field within the examination region 14.

A whole-body radio frequency coil 30, such as a stripline coil, SENSE coil elements, a birdcage coil, or the like, is arranged in the housing 12 surrounded by an RF shield 32 to inject radio frequency excitation pulses into the examination region 14 and to detect generated magnetic resonance signals. For generating images of limited regions of the subject 16, an RF coil arrangement or system 34 is used which includes one or more local RF coil assemblies 36, each including one or more RF coil elements 38, which are placed contiguous to the selected region.

With continuing reference to FIG. 1, a magnetic resonance imaging (MRI) controller 46 executes and coordinates parallel data acquisition in a first or primary scanning session or process 48 and a second, secondary, or background session or process 50. The imaging controller 46 operates magnetic field gradient amplifiers or controllers 52 coupled to the gradient coils 28 to superimpose selected magnetic field gradients on the main magnetic field in the examination region 14, and also operates a radio frequency transmitter or transmitters 54 coupled to the radio frequency coil 30 as shown, and/or to the local coil 36, surface coil, coils array, or so forth, to inject selected radio frequency excitation pulses at about the magnetic resonance frequency into the examination region 14 in accordance with one of selected scanning sequences. The radio frequency excitation pulses excite magnetic resonance signals in the imaging subject 16 that are spatially encoded by the selected magnetic field gradients. Still further, the imaging controller 46 operates a radio frequency receiver or receivers 56 that are connected with the radio frequency coil elements 38 (or the coil 30) in accordance with the selected magnetic resonance imaging sequence to receive the radial readout magnetic resonance signals. A workflow manager, processor, mechanism, algorithm, or other means 58 continually monitors the first scanning process 48. More specifically, the workflow manager 58 monitors for any periods of inactivity in performing the first or primary scanning session 48 and, when such periods of inactivity are detected, initiates scans of the background scanning session 50. Such background scans can be acquisitions that are slow due, for example, to contrast and resolution requirements, compatible with the primary scanning session, do not violate the cumulative SAR regulations and do not require patient cooperation. The examples of the secondary scans include coronary artery imaging, MR spectroscopy or spectroscopic imaging (brain or other organ), flow studies (blood, CSF etc.), inflow or phase contrast angiography, 3 D volumetric anatomical scans (i.e., MP-RAGE), and additional averages or higher frequency k-space regions of previously acquired anatomical scans. The received readout data of the primary scanning session 48 are stored in a first data memory 68, while the received radial readout data of the secondary scanning session 50 are stored in a second data memory 70.

A reconstruction processor, algorithm, device, or other means 72 reconstructs the stored magnetic resonance data into reconstructed images of the imaging subject 16 or a selected portion thereof lying within the examination region 14. The reconstruction processor 72 employs a Fourier transform reconstruction technique or other suitable reconstruction technique that comports with the spatial encoding used in the data acquisition. While the reconstruction processor 72 reconstructs the images taken in the first or primary scanning session 48 contemporaneously with the data acquisition, the images taken in the secondary scanning session 50 are reconstructed after the entire data set is acquired. Alternately, the secondary image reconstruction can be commenced using reconstruction processor resources, if any, that the primary scan reconstruction is temporarily not employing. The reconstructed images are stored in an image memory 74, and can be displayed on a user interface 76, transmitted over a local area network or the Internet, printed by a printer, stored in a database, or otherwise utilized. In the illustrated embodiment, the user interface 76 also enables a radiologist or other user to interface with the imaging controller 46 to select, modify, or execute imaging sequences. In other embodiments, separate user interfaces are provided for operating the scanner 10 and for displaying or otherwise manipulating the reconstructed images.

The described magnetic resonance imaging system 8 is an illustrative example. In general, substantially any magnetic resonance imaging scanner can incorporate the disclosed radio frequency coils. For example, the scanner can be an open magnet scanner, a vertical bore scanner, a low-field scanner, a high-field scanner, or so forth. In the embodiment of FIG. 1, separate transmit and receive coils are illustrated; however, one or more of the radio frequency coils 30, 36 can be used for both transmit and receive phases of the magnetic resonance sequence.

With continuing reference to FIG. 1 and further reference to FIG. 2, the imaging controller 46 performs the first or primary and second or secondary scanning sessions 48, 50 interleaved, in parallel acquisition and processing streams. More specifically, the patient 16 arrives for the exam and is placed 90 on the patient bed 18 with any appropriate local RF coil or monitoring devices attached. The MRI controller 46 performs 92 an initial survey or pilot scan to get a general overview of patient position and orientation. The technologist or medical professional performs 94 planning for scan 1 of the primary scanning session 48. After the scan 1 is submitted, the MRI controller 46 initiates scan 1 of the primary scanning session 48. While scan 1 of the primary scanning session 48 is being performed 96, the medical professional plans 100 the background scanning session 50. For example, once scan 1 of the first scanning session is completed, the technologist plans and sets up 102 for scan 2 based on the results of scan 1 and optionally the initial survey. During this planning and set-up period 102 for scan 2, the workflow manager 58 detects that the scanner is idle, e.g. the first scanning session 48 is inactive. The workflow manager starts 104 the background scanning session 50. The data acquired for the background scanning session 50 is stored in the second data memory 70. Once the technologist has prepared an acquisition for scan 2 of the first scanning session 48, the technologist submits a start scan 2 request to the imaging controller 46. The workflow processor 58 suspends the background scanning session 50, as the priority is given to the primary scanning session 48. Scan 2 of the primary scanning session 48 is performed 106. For example, scan 2 may have a substantial reconstruction load which requires a reconstruction delay 110. The workflow manager 58 detects the reconstruction delay 110, and starts 112 the continuation of the background scanning session 50 until another scan 120 of the primary scanning session 48 is ready to start acquiring data. For example, scan 3 of the first scanning session 48 includes a series of breath-holds 122, 124, 126, 128, 130, during each of which scan 3 data is acquired. During such scan sequence 120, the patients are typically asked to hold their breaths for about 10 or 20 seconds. After each breath-hold, the patients are given comparable time periods 142 to rest and recover in between breath-holds. The workflow manager 58 detects the rest periods 142 and initiates acquiring 150 data for the background scanning session 50 during the rest periods 142. After scan 3 is completed, the data is reconstructed and the technologist, for example, may review 152 the acquired data, perform post-processing, send data to PACS, or wait for a clinician feedback on any additional scanning that should be performed. The workflow manager 58 detects such period of inactivity in the primary scanning session 48 and initiates acquiring 154 the background scanning session data.

In the manner described above, the workflow of the imaging system 8 is optimized to allow a slower scan to run in periods of inactivity of the primary scan when the technologist sets up new acquisitions, performs post-processing, awaits additional instructions from clinical reviewers, awaits reconstruction, or is allowing the patient recovery time during or following a set of breath-holds. For example, such slower scan is passive, e.g. it is not predicated on specific instructions given to the patient such as breath-holding. Such scan is amenable to piecewise acquisition with a minimum of pre-pulses or dummy shots required to achieve a steady state signal profile comparable to if it had been acquired consecutively. Acquisitions with relatively long repetitions times (TR), which also tend to be slower acquisitions, are inherently well adapted to this requirement since magnetization stimulated in one TR is almost completely restored by the time of the next excitation. Elongation of this period, as would happen if the background scan was suspended, therefore has little impact. In some instances it may be necessary to play out a dummy acquisition prior to the resumption of the background scan in order to avoid artifact.

Of course, if the background scan 50 is preselected or selected automatically as a consequence of the initial set up 90, the background scanning session 50 can start during a remaining portion of the set up period 90 and can be recommenced in the scan 1 planning period 92. Two or more secondary scans can be acquired. The secondary scan 50 may also collect scan data for scan 2 or scan 3. For example, in the secondary scanning period 104, the secondary scanning session 50 may acquire data for scan 3 when the patient has inhaled and data for scan 2 at other times. Also, the secondary session 50 can repeat scan 1 to provide redundant images for averaging. As another variation, in the three scan example, one of the three scans can be completely acquired in the secondary session 50.

Since the background acquisition is acquired throughout the study, the data acquired for the background scan 50 is reconstructed when the entire scan is completed. Moreover, since the background acquisition can start up between scans, while a primary scan 48 is reconstructing, or even during a rest period within a scan, such as breath-hold break, in one embodiment, the system rapidly exchanges gradient, RF and data acquisition instructions with the relevant hardware components of the MR system. Alternatively, the system performs parallel data acquisition and storage chains that are switched between depending on whether the primary or background acquisition is active.

The parallel data acquisition described above is specifically applicable to applications such as coronary artery imaging. Since the coronary arteries move substantially with both cardiac contraction and respiration, typically, the steps are taken to avoid the effects of this motion in coronary artery images. A typical approach is to limit MR data acquisition to a short period (˜100 ms) in late diastole and to additionally only accept data when the diaphragm is within a few mm of its end-expiration position. This effectively limits any motion during image acquisition but results in a very low efficiency and correspondingly prolonged image acquisitions times (typically 5-20 minutes). Since the patient's cardiac and respiratory cycles are passively monitored, however, the technique has the substantial benefit of not requiring patient compliance. Similarly, since data acquisition shots are separated by at least one cardiac cycle, there is substantial recovery between shots and therefore suspension and resumption of the acquisition have minimal impact. Finally, cardiac exams tend to be relatively long and have substantial periods of scanner inactivity due to the frequent use of breath-holding techniques, which predicates the need for substantial periods of patient recovery. Cardiac exams also frequently require additional clinician review and post-processing, which also increase the periods of time that the scanner is inactive.

In one embodiment, in the second scanning session 50, a different region of the patient is imaged. For example, while the cardiac region is imaged in the first scanning session 48, the brain is imaged in the second scanning session 50. The patient might be slightly readjusted or moved.

The invention has been described with reference to the preferred embodiments. Modifications and alterations may occur to others upon reading and understanding the preceding detailed description. It is intended that the invention be constructed as including all such modifications and alterations insofar as they come within the scope of the appended claims or the equivalents thereof.

1. An imaging system comprising:
an imaging controller which performs data acquisition in first and second scanning processes, the first scanning process including a set of data acquisitions and periods of inactivity; and
a workflow manager which monitors the first scanning process, detects the periods of inactivity and enables data acquisition of the second scanning process when the first scanning process is inactive.

2. The system as set forth in claim 1, wherein the second scanning process includes at least one of:
a slow scan;
a high resolution scan; and
a long time duration scan.

3. The system as set forth in claim 1, wherein the first scanning process includes at least one of:
a magnetic resonance imaging of a coronary artery;
magnetic resonance flow studies;
spectroscopy; and
spectroscopic imaging.

4. The system as set forth in claim 1, wherein the periods of inactivity of the first scanning process include at least rest periods between breath-hold periods, during which magnetic resonance imaging of the coronary artery is performed.

5. The system as set forth in claim 1, wherein the periods of inactivity of the first scanning process include at least one of:
planning a subsequent scan;
a reconstruction delay; and
post-processing of data acquired in the first scanning process.

6. The system as set forth in claim 1, wherein the workflow manager automatically one of starts and resumes the data acquisition of the second scanning process when the period of inactivity in the first scanning process is detected and automatically suspends the data acquisition of the second scanning process when a submission of new data acquisition of the first scanning process is detected.

7. A magnetic resonance imaging scanner, which acquires data in the imaging system set forth in claim 1; and
a reconstruction processor, which reconstructs the data acquired by the magnetic resonance imaging scanner in the first and second scanning processes, into volumetric image representations.

8. An imaging method comprising:
intermittently acquiring data for a first scanning process;
monitoring the first scanning process;
detecting periods of inactivity in the first scanning process which occur when the data in the first scanning process is not being acquired; and
acquiring the data for a second scanning process when the first scanning process is inactive.

9. The method as set forth in claim 8, wherein the step of acquiring the data in the second scanning process includes at least one of:
acquiring slow scan data;
acquiring high resolution scan data; acquiring long time duration scan data;
acquiring spectroscopic data;
acquiring redundant first scanning process data; and
acquiring non-redundant data for one or more scans of the first scanning process.

10. The method as set forth in claim 9, further including:
automatically one of starting and resuming the data acquisition in the second scanning process when a start of each period of inactivity is detected; and
automatically suspending the data acquisition in the second scanning process when a new data acquisition request is submitted in the first scanning process.

11. The method as set forth in claim 8, wherein the step of periodically acquiring the data in the first scanning process includes one of:
magnetic resonance imaging of a coronary artery;
magnetic resonance imaging of flowing liquid; spectroscopy; and spectroscopic imaging.

12. The method as set forth in claim 8, wherein the periods of inactivity of the first scanning process include:
at least rest periods between breath-hold periods.

13. The method as set forth in claim 12, wherein the step of acquiring the data for the second scanning process includes:
acquiring the data for the second scanning process during the rest periods.

14. The method as set forth in claim 8, wherein the periods of inactivity of the first scanning process include at least one of:
planning a subsequent scan;
a reconstruction delay; and
post-processing of the data acquired in the first scanning process.

15. The method as set forth in claim 8, wherein the step of acquiring the data for the first scanning process includes:
performing initial survey scan of a subject during a first time;
performing a first scan of the subject during a second time;
performing a second scan of the subject during a third time; and
performing a third scan of the subject during a series of breath-hold time periods.

16. The method as set forth in claim 15, wherein the step of acquiring the data for the second scanning process includes:
acquiring the data in the second scanning process during at least one of a time period between:
the first and second time,
the second and third time,
the third time and a first breath-hold time period; and
each two adjacent breath-hold time periods.

17. The method as set forth in claim 16, wherein the step of acquiring the data for the second scanning process further includes:
acquiring the data in the second scanning process during a step of post processing of the data acquired in the first scanning process.

18. A computer processor or algorithm, which controls a magnetic resonance scanner to acquire data for the first and second scanning processes as set forth in claim 8.

19. An imaging apparatus comprising:
an imaging controller which executes data acquisition in first and second scanning processes, the first scanning process including a set of data acquisitions and periods of inactivity; and
a workflow manager programmed to perform the method of claim 8.

20. An imaging apparatus comprising:
an imaging controller which executes data acquisition in first and second scanning processes, the first scanning process including a set of data acquisitions and periods of inactivity;
a workflow manager which performs the steps of:
continually monitoring the first scanning process;
detecting a start of each period of inactivity in the first scanning process which period of inactivity occurs when the data in the first scanning process is not being acquired;
automatically one of starting and resuming the data acquisition in the second scanning process when the start of each period of inactivity is detected, and
automatically suspending the data acquisition in the second scanning process when a new data acquisition request is submitted in the first scanning process; and
a reconstruction processor, which reconstructs (a) the data acquired in the first scanning process after each data acquisition request is completed and (b) the data acquired in the second scanning process.
